(19) United States
(12) Patent Application Publication
(10) Pub. No.: US 2019/0006434 A1
(43) Pub. Date: Jan. 3, 2019

(54) ORGANIC LIGHT EMITTING DISPLAY PANEL AND DISPLAY DEVICE

(71) Applicant: Shanghai Tianma AM-OLED Co., Ltd., Shanghai (CN)

(72) Inventors: Wanming HUA, Shanghai (CN); Jinghua NIU, Shanghai (CN); Xiangcheng WANG, Shanghai (CN); Yuji HAMADA, Shanghai (CN)

(21) Appl. No.: 15/862,787

(22) Filed: Jan. 5, 2018

(30) Foreign Application Priority Data
Jun. 29, 2017 (CN) 201710515818.0

(51) Int. Cl. H01L 27/32; H01L 51/52; H01L 51/50

(52) U.S. Cl. CPC H01L 27/3209; H01L 51/5206; H01L 51/5092; H01L 51/5221

(57) ABSTRACT

Embodiments of the present disclosure relate to technical fields of organic light emitting display, and provide an organic light emitting display panel and a display device, which can improve the use efficiency of output light in the top emission configuration. The organic light emitting display panel includes a negative and anode layers, and a substrate. A minimum transmittance of the cathode layer in visible light band is greater than 80%. A reflectivity of the anode layer in visible light band is greater than 90%. An organic material layer is placed between the negative and anode layers. The organic material layer includes a first electron transmission layer doped with a metal whose activity is stronger than activity of magnesium. The substrate, the anode layer, the organic material layer, and the cathode layer are placed in order along a direction of light output of the organic light emitting display panel.

### CROSS-REFERENCE TO RELATED APPLICATIONS

The present application claims the benefit of priority to Chinese Patent Application No. 201710515818.0, filed on Jun. 29, 2017, the content of which is incorporated herein by reference in its entirety.

### TECHNICAL FIELD

The present invention relates to the technical field of organic light emitting display technologies and, particularly, relates to an organic light emitting display panel and a display device.

### BACKGROUND

An organic light emitting display device is also called as an organic light emitting diode (OLED) display device. Compared with a liquid crystal display device, the organic light emitting display device has advantages of light weight, and wide visual angle.

Conventional organic light emitting display devices include a top emission configuration and a bottom emission configuration. In the top emission configuration, an organic light emitting member of the organic light emitting display device includes a translucent cathode and a totally reflective anode. However, the translucent cathode may generate a strong microcavity effect, which results in low utilization of output light.

### SUMMARY

Embodiments of the present disclosure provide an organic light emitting display panel and a display device, which can improve the utilization of output light in the top emission configuration.

In one aspect, the present disclosure provide an organic light emitting display panel, including: a cathode layer; an anode layer; an organic material layer placed between the cathode layer and the anode layer, the organic material layer including a first electron transmission layer, the first electron transmission layer being doped with a metal whose activity is stronger than magnesium; and a substrate; wherein a minimum transmittance of the cathode layer in visible light band is greater than 80%; a reflectivity of the anode layer in visible light band is greater than 90%; and wherein the substrate, the anode layer, the organic material layer, and the cathode layer are placed in order along a light outputting direction of the organic light emitting display panel.

In another aspect, the present disclosure provides a display device. The display device includes the organic light emitting display panel described as above.

In the organic light emitting display panel and the display device of embodiments of the present disclosure, by doping the metal whose activity is stronger than activity of magnesium into the first electron transmission layer, the first electron transmission layer is capable of directly injecting electrons into the light emitting layer to make the light emitting layer emit light, so that it is unnecessary for the cathode layer to inject electrons into the light emitting layer, and a transparent conductive layer can be used as the cathode layer. Since the transmissivity of the transparent conductive layer is relatively high, the microcavity effect generated is poor, thereby improving the use efficiency of output light in the top emission configuration.

### BRIEF DESCRIPTION OF DRAWINGS

In order to more clearly illustrate technical solutions of embodiments of the present disclosure, the required accompanying drawings used in the embodiments will be briefly described as follows. Apparently, drawings in the following description are only some embodiments of the present disclosure. For those with ordinary skill in the art, without having to pay any creative labor, other accompanying drawings can also be obtained according to these accompanying drawings.

FIG. 1 illustrates a partial structural schematic diagram of an organic light emitting display panel according to an embodiment of the present disclosure;

FIG. 2 illustrates a partial structural schematic diagram of another organic light emitting display panel according to an embodiment of the present disclosure;

FIG. 3 illustrates a partial structural schematic diagram of another organic light emitting display panel according to an embodiment of the present disclosure;

FIG. 4 illustrates a partial structural schematic diagram of another organic light emitting display panel according to an embodiment of the present disclosure; and

FIG. 5 illustrates a structural schematic diagram of a display device according to an embodiment of the present disclosure.

### DESCRIPTION OF EMBODIMENTS

In order to better understand the technical solutions, the embodiments of the present disclosure are described in details as below with reference to the accompanying drawings.

It will be appreciated that described embodiments herein are only a part of embodiments of the disclosure, rather than all the embodiments. Based on the embodiments in the present disclosure, all other embodiments obtained by those of ordinary skill in the art without any creative work shall fall into the scope of protection of the present disclosure.

The terms used in the embodiments of the present disclosure are merely for describing specific embodiments, and are not intended to limit the present disclosure. Unless otherwise clearly noted in the context, the “a”, “an”, “the” and “said” used in a singular form in the embodiments and claims of the present disclosure are also intended to represent a plural form thereof.

It should be appreciated that term “and/or” used herein is only a kind of incidence relation for describing related object, which may express three kinds of relations. For example, “A and/or B” can represent the following three situations: there is only A, there is A and B at the same time, and there is only B. In addition, character “/” generally means a kind of relation of “or” between associated objects.

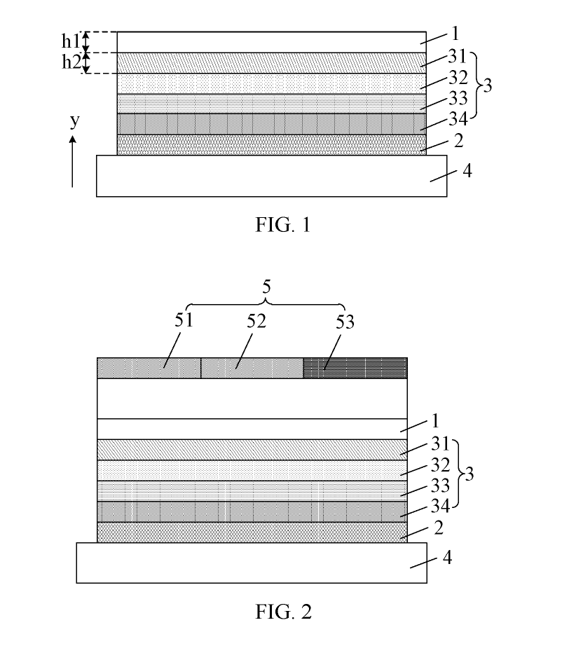

FIG. 1 illustrates a partial structural schematic diagram of an organic light emitting display panel according to an embodiment of the present disclosure. As shown in FIG. 1, the organic light emitting display panel includes a cathode layer 1 and an anode layer 2. A minimum transmissivity of the cathode layer in a visible band is greater than 80%, and that is to say, the cathode layer 1 is a transparent electrode. A reflectivity of the anode layer 2 in the visible band is greater than 90%, and that is to say, the anode layer 2 is a totally reflective electrode. An organic material layer 3 is placed between the cathode layer 1 and the anode layer 2. The organic material layer 3 includes a first electron transmission layer 31 directly contacting with the cathode layer 1, and a substrate 4. The first electron transmission layer 31 is doped with a metal whose activity is stronger than activity of magnesium. The substrate 4, the anode player 2, the organic material layer 3, and the cathode layer 1 are placed in order along a light outputting direction y of the organic light emitting display panel.

Further, the cathode layer 1, the organic material layer 3, and the anode layer 2 cooperatively form an organic light emitting unit. A pixel circuit layer (not shown in the figure) is placed on the substrate 4, which is used for controlling the organic light emitting unit. The activity of metal refers to difficulty level in which the metal itself loses electrons, the stronger the activity, and the more easily the metal loses electrons, and the poorer the activity, and the more difficult the metal loses electrons. When the transparent electrode is used as the cathode layer 1, a work function of the transparent electrode is relatively high, and then electrons cannot be injected into the light emitting layer of the organic material layer 3. While after the first electron transmission layer 31 is doped with metal whose activity is stronger than activity of magnesium, electrons can be directly injected into the light emitting layer by the first electron transmission layer 31, thereby making the light emitting layer emit light without injecting electrons into the light emitting layer by the cathode layer 1.

It should be noted that, a so-called square resistance refers to a resistance between two opposite edges of a thin conductive film shaped as a square. The square resistance has a feature that resistance between two opposite edges of the square in any size is the same. No matter the length of the edge is 1 m or 0.1 m, their square resistances are the same. Thus, the square resistance is only related to a thickness of the conductive film.

Table 1

TABLE 1

| | Whether the | Thick- | | | Average |
|---|---|---|---|---|---|
| | electron | ness | | | voltage |
| | transmission | of the | | | of the |
| | layer is | electron | | | organic |
| | doped with | trans- | | Number | light |
| | ytterbium | mission | Cathode | of | emitting |
| | or not | layer | material | lightening | unit |
| Comparative | no | 35 nm | Al | 94 | 3.6 |
| example 1 | | | | | |
| Comparative | no | 35 nm | ITO | 0 | / |
| example 2 | | | | | |
| Comparative | yes | 35 nm | ITO | 92 | 3.2 |
| example 3 | | | | | |
| Comparative | yes | 170 nm | ITO | 94 | 3.3 |
| example 4 | | | | | |

As shown in Table 1, data of four comparative examples are listed, and each comparative example is implemented by preparing 100 pieces of organic light emitting display panels. Except for the configurations of the electron transmission layer and the cathode, other configurations of the four comparative examples are the same. Upon comparison of the comparative example 1 and the comparative example 2, a yield of the cathode made of indium tin oxide (Indium Tin Oxide, ITO) is zero, which demonstrates that, when the electron transmission layer is not doped with ytterbium, aluminum as a cathode can inject electrons into the unit, while ITO as the cathode cannot inject electrons into the unit. Upon comparison of the comparative example 2 and the comparative example 3, it is demonstrated that the electron transmission layer doped with ytterbium can successfully inject electrons into the unit.

In the organic light emitting display panel of the embodiment of the present disclosure, the first electron transmission layer is doped with metal whose activity is stronger than the activity of magnesium, so that the first electron transmission layer is capable of directly injecting electrons into the light emitting layer to make the light emitting layer emit light. Thus, it is unnecessary for the cathode layer to inject electrons into the light emitting layer, and a transparent conductive layer can be used as the cathode layer. Since the transmissivity of the transparent conductive layer is relatively high, the generated microcavity effect is weak, thereby improving the utilization of output light in the top emission configuration.

Optionally, the square resistance of the cathode layer 1 is smaller than or equal to 10 Ω/□.

In the prior art, a cathode layer is usually made of relatively thin metal material, to achieve translucent effect. However, the thinner the metal cathode, the greater its area resistance, and accordingly, the more easily a problem of non-uniformity of display brightness occurs due to decrease of a pressure drop of the voltage transmitted on the cathode layer. In the organic light emitting display panel of the present embodiment, the square resistance of the cathode layer is smaller than or equal to 10 Ω/□, so that a conductivity of the cathode layer is improved, thereby improving uniformity of display brightness.

Optionally, the thickness h1 of the cathode layer 1 is greater than or equal to 2400 angstroms.

The cathode layer 1 is used for transmitting a power supply voltage to different positions of the display panel, and because of the square resistance of the cathode layer 1, voltage values at different positions of the display panel when transmitted from a voltage source to the display panel are different from each other. Considered the size of a panel, for keeping the uniformity of brightness at different positions when transmitted from the voltage source to the display panel in an acceptable range, the thickness h1 of the cathode layer 1 is required to be greater than or equal to 2400 angstroms.

Optionally, the cathode layer 1 is made of ITO, indium zinc oxide, or a mixture of ITO and indium zinc oxide.

Those materials are all oxide materials, thereby avoiding problems of cathode oxidation when using metal with relatively strong activity as the cathode. Thus, a problem of performance degradation of the organic light emitting unit caused by cathode oxidation is avoided. The cathode layer 1 can be formed by a low-temperature sputtering method, and a temperature of the substrate is about in a range of from room temperature to 80° C. By the low-temperature method, the organic material layer 3 won't be damaged during a formation process of the cathode layer due to its poor heat resistance. For example, when ITO is used as material of the cathode layer 1, the thickness of the cathode layer 1 is about 2400 angstroms, and the square resistance of the cathode layer 1 is 10 Ω/□; when indium zinc oxide is used as material of cathode layer 1, the thickness of the cathode layer 1 is about 4000 angstroms, and the square resistance of the cathode layer 1 is 10 Ω/□; and a mixture of ITO and indium zinc oxide with a mass ratio of 1:1 is used as material of the cathode layer 1, the thickness of the cathode layer 1 is about 8000 angstroms, and the square resistance of the cathode layer 1 is 10 Ω/□.

Optionally, the cathode layer 1 is doped with metal material.

For reducing the square resistance of the cathode layer 1, the greater the thickness h1 of the cathode layer 1 the better. However, when the thickness h1 of the cathode layer 1 is relatively great, the integral transmissivity is relatively low, material consumption is increased, a preparing process is prolonged, and the cost is increased, which are adverse to mass manufacturing. Thus, the cathode layer 1 is doped with metal material, in order to improve the conductivity of the cathode layer 1, thereby decreasing the thickness h1 of the cathode layer 1.

Optionally, a volume percentage of the metal material in the cathode layer 1 is smaller than 5%.

The metal material is lightproof, and the greater the volume percentage of the metal material in the cathode layer 1, the lower the transmissivity of the cathode layer 1; and the smaller the volume percentage of the metal material in the cathode layer 1, the higher the transmissivity of the cathode layer 1. Thus, considering the transmissivity of the cathode layer 1, it is selected that an atom percentage of the metal material in the cathode layer 1 is smaller than 2%. For example, the square resistance of the cathode layer 1 is 10 Ω/□ when ITO is used as the material of the cathode layer 1, the thickness of the cathode layer 1 is about 2400 angstroms when the cathode layer 1 is not doped with metal, and the transmissivity is assumed to be x; when the cathode layer 1 is doped with silver with the atom percentage of 0.5%, and the transmissivity is maintained at x, the thickness of the cathode layer 1 decreases by 30% to be about 1680 angstroms, the square resistance decreases by 30% to be about 7 Ω/□; when the cathode layer 1 is doped with silver with the atom percentage of 2%, the square resistance decreases by 50%, while the transmissivity decreases significantly.

Optionally, the metal material is gold, silver, copper, or aluminum.

The greater the conductivity of the metal material doped in the cathode layer 1, the higher the conductivity of the cathode layer 1, so that the metal material doped in the cathode layer 1 is selected from metals with high conductivity, such as gold, silver, copper, and aluminum. In addition, the greater the ratio of the metal material in the cathode layer 1, the lower the transmissivity of the cathode layer 1, meanwhile the higher the conductivity of the cathode layer 1; and the smaller the ratio of the metal material in the cathode layer 1, the higher the transmissivity of the cathode layer 1, meanwhile the lower the conductivity of the cathode layer 1. Accordingly, the selection of the metal material and the ratio of the metal material in the cathode layer 1 can be determined according to the above-described principle.

Optionally, a thickness h2 of the first electron transmission layer 31 is greater than 1000 angstroms.

Please refer to comparative example 3 and comparative example 4, upon comparison of data of comparative example 3 and comparative example 4, when a thickness of the electron transmission layer increases, the thickness increase has little effect on the voltage of the unit due to relatively fast electron mobility of the electron transmission layer doped with metal ytterbium, meanwhile a thicker transmission layer can bring higher yield.

During a making process for the organic light emitting display panel, in order to prepare the cathode layer 1 after the organic material layer 3 is prepared, the sputtering method is required for the preparation of the cathode layer 1, while in the sputtering process, impact on other film layers is relatively great, which may result in surface irregularity of the first electron transmission layer 31. If the thickness h2 of the first electron transmission layer 31 is relatively smaller, the surface irregularity of the first electron transmission layer 31 has a great adverse effect on the luminous performance; and if the thickness h2 of the first electron transmission layer 31 is greater than 1000 angstroms, the adverse effect on the luminous performance is little and in an acceptable range.

Optionally, a volume percentage of the metal whose activity is stronger than magnesium in the first electron transmission layer 31 is in a range of 1%-5%.

When the ratio of metal in the first electron transmission layer 31 is relatively high, optical absorption and metal dipole action are strong, which will decrease luminous efficiency and extraction efficiency; while when the ratio of metal in the first electron transmission layer 31 is relatively small, it is difficult to control in the production process, and metal and electron transmission material cannot cooperatively form a complex in order to generate electrons. Therefore, for both reasons, the volume percentage of the metal in the first electron transmission layer 31 is in a range of 1%-5%.

Optionally, the metal whose activity is stronger than magnesium is selected from a group consisting of lithium, sodium, calcium, cesium, and ytterbium.

Those metals have characteristics of low melting point and easy evaporation, so that those metals can be easily doped in a preparing process of the electron transmission layer.

Optionally, the metal whose activity is stronger than magnesium is ytterbium.

The first electron transmission layer 31 doped with ytterbium has a characteristic of high mobility, which is favor of injection of electrons into the light emitting layer when the thickness of the first electron transmission layer 31 is relatively great. In addition, when doping metal in the first electron transmission layer 31, a required thermal evaporation temperature for metal ytterbium is relatively low, which result in that the a process realization is simple.

Optionally, the first electron transmission layer 31 includes a functional group shown as formula I, and any hydrogen atom in the functional group shown as formula I is available to be substituted to form a substituent group,

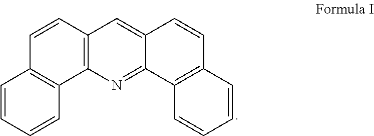 [SMILES: c1ccc2c(c1)ccc1cc3ccc4ccccc4c3nc12]

Optionally, the first electron transmission layer 31 includes a compound shown as formula II,

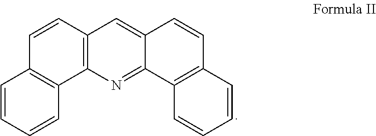 [SMILES: c1ccc2c(c1)ccc1cc3ccc4ccccc4c3nc12]

That is, the first electron transmission layer 31 includes an electron transmission material, such as the functional group shown as formula I and the compound shown as formula II. The electron transmission material can cooperate with metal ytterbium doped in the first electron transmission layer 31 to form a complex, so that a higher electron mobility can be achieved in the first electron transmission layer 31.

Optionally, the organic material layer 3 includes the first electron transmission layer 31, the light emitting layer 32, a hole transmission layer 33, and a hole injection layer 34 placed in order along a direction from the cathode layer 1 to the anode layer 2.

During working of the organic light emitting display panel of the embodiment of the present disclosure, under an electric field action of the cathode layer 1 and the anode layer 2, ytterbium in the first electron transmission layer 31 and the electron transmission material cooperatively form the complex, electrons are generated by the complex in the electron transmission layer and transmitted to the light emitting layer 32, holes are injected from the anode layer 2 and transmitted to the light emitting layer 32 through the hole transmission layer 33, and in the light emitting layer 32, electrons and holes combine, such that it is achieved that light is emitted.

Optionally, FIG. 2 illustrates a partial structural schematic diagram of anther organic light emitting display panel according to an embodiment of the present disclosure. As shown in FIG. 2, the organic material layer 3 includes an organic material layer 3 used for generating white light. The organic light emitting display panel further includes a color filter layer 5 placed on one side of the cathode layer 1 away from the anode layer 2.

For a red-green-blue tricolor organic light emitting display panel, it is required that three colors are respectively evaporated by various fine masks, and high precision of the fine masks are needed, which easily results in defects in the making process. However, for an organic light emitting display panel for emitting white light, the fine masks are not required to be used, and requirements for the making process are lower, which is a present development trend. In the present disclosure, the organic material layer 3 for generating white light can generate white light, and for achieving colorful display, in the embodiments of the present disclosure, the color filter layer 5 is required for filtering the white light generated by the organic material layer 3. For example, the color filter layer 5 includes a blue color resistor 51, a green color resistor 52, and a red color resistor 53. A conventional organic light emitting display device for emitting white light includes a top emission configuration and a bottom emission configuration. In the top emission configuration, the organic light emitting unit of the organic light emitting display device includes a translucent cathode and a totally reflective anode. However, since light may be reflected repeatedly between the translucent cathode and the totally reflective anode, a relatively strong microcavity effect may be generated, and then a luminescent spectrum of white light may be affected. While, in the bottom emission configuration, since a circuit is placed on the substrate, an aperture ratio for the bottom emission configuration is lower than an aperture ratio for the top emission configuration, and multiple passivation layers and protective layers are placed on the substrate, which may absorb light and affect chromaticity coordinate and viewing angle color cast of white light. In the top emission configuration of the embodiments of the present disclosure, by using transparent conductive layer as the cathode layer, the microcavity effect is decreased, thereby decreasing the adverse influence on white luminescent spectrum. Compared with the bottom emission structure, since light does not pass through the substrate, light consumption decreases, the adverse influence on color coordination and chromaticity coordinate and viewing angle color cast of white light decrease, and the aperture ratio is increased.

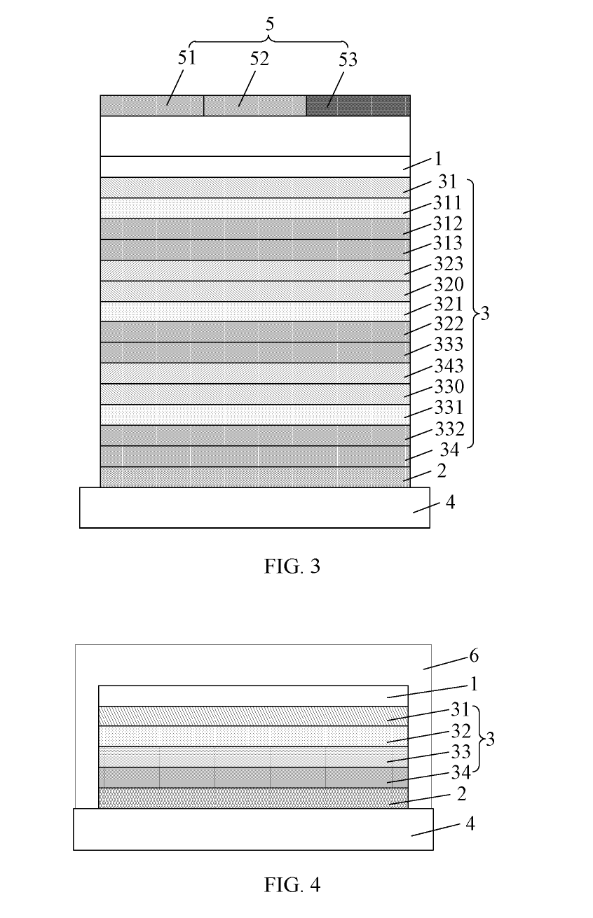

FIG. 3 illustrates a partial structural schematic diagram of anther organic light emitting display panel according to an embodiment of the present disclosure. As shown in FIG. 3, the organic material layer 3 includes a first electron transmission layer 31, a first light emitting layer 311, a first hole transmission layer 312, a first charge generation layer 313, a second charge generation layer 323, a second electron transmission layer 320, a second light emitting layer 321, a second hole transmission layer 322, a third charge generation layer 333, a fourth charge generation layer 343, a third transmission layer 330, a third light emitting layer 331, a third hole transmission layer 332, and a hole injection layer 34 placed in order along a direction from the cathode layer 1 to the anode layer 2.

The organic material layer 3 used for generating white light can achieve highly efficient, stable white light by stacking light emitting layers of different colors, or by other methods. The method for generating white light is not limited in embodiments of the present disclosure. The first light emitting layer 311, the second light emitting layer 321, and the third light emitting layer 331 are light emitting layers for generating different colors, respectively. The first light emitting layer 311 is closest to the cathode layer 1, so that the first electron transmission layer 31 is placed between the first light emitting layer 311 and the cathode layer 1, and ytterbium in the first electron transmission layer 31 and the electron transmission material cooperatively form a complex, by which electrons are generated in the electron transmission layer and transmitted to the first light emitting layer 311. The first charge generation layer 313 includes a p-type dopant and a hole transmission material for generating holes, holes generated by the first hole generation layer 313 are transmitted to the first light emitting layer 311 through the first hole transmission layer 312. In the first light emitting layer 311, electrons and holes combine to emit light. The second charge generation layer 323 includes an N-type dopant and an electron transmission material for generating electrons, and electrons generated by the second charge generation layer 323 are transmitted to the second light emitting layer 321 through the second electron transmission layer 320. The third charge generation layer 333 includes a P-type dopant and a hole transmission material for generating holes, holes generated by the third charge generation layer 333 are transmitted to the second light emitting layer 321 through the second hole transmission layer 322. In the second light emitting layer 321, electrons and holes combine to emit light. The fourth charge generation layer 343 includes an N-type dopant and an electron transmission material for generating electrons, and electrons generated by the fourth charge generation layer 343 are transmitted to the third light emitting layer 331 through the third electron transmission layer 330. Holes in the anode layer 2 are injected into the hole injection layer 34 and transmitted to the third light emitting layer 331 through the third hole transmission layer 332, and electrons and holes in the third light emitting layer 331 combine to emit light.

Optionally, the first light emitting layer 311 is one of a blue-light emitting layer, a green-light emitting layer, and a red-light emitting layer, the second light emitting layer 321 is another one of the blue-light emitting layer, the green-light emitting layer, and the red-light emitting layer, and the third light emitting layer 331 is the remaining one of the blue-light emitting layer, the green-light emitting layer, and the red-light emitting layer. For example, the first light emitting layer 31 is the red-light emitting layer, the second light emitting layer 321 is the green-light emitting layer, and the third light emitting layer 331 is the blue-light emitting layer. Light of different colors mix to emit white light by overlapping the three light emitting layers of three colors. Meanwhile, if there is no charge generation layer, a light emitting central position may be any position in the red-green-blue tricolor light emitting layer, so that a color cast of a mixed light is caused and the luminous efficiency is low. While in embodiments of the present disclosure, the charge generation layers are included, each of the red-light emitting layer, the green-light emitting layer, and the blue-light emitting layer has one light emitting central position, so that the white spectrum and the luminous efficiency are better.

Optionally, as in shown in FIG. 3, both the second charge generation layer 323 and the fourth charge generation layer 343 include an N-type dopant and an electron transmission material. The N-type dopant is ytterbium. The electron transmission material includes a functional group shown as formula I or a compound shown as formula II. Any hydrogen atom in the functional group shown as formula I is available to be substituted to form a substituent group.

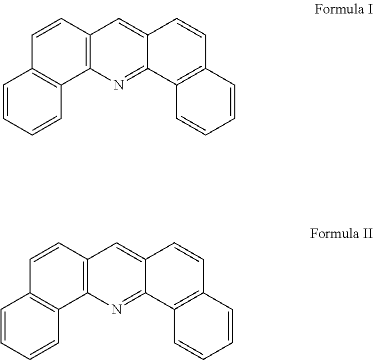 [SMILES: c1ccc2c(c1)ccc1cc3ccc4ccccc4c3nc12 ; c1ccc2c(c1)ccc1cc3ccc4ccccc4c3nc12]

Since the first electron transmission layer 31 is doped with ytterbium and includes the above electron transmission material, a function of a charge generation layer for generating electrons can be achieved, so that the first electron transmission layer 31, the second charge generation layer 323, and the fourth charge generation layer 343 can be formed by the same making process, thereby reducing a process difficulty.

Optionally, FIG. 4 illustrates a partial structural schematic diagram of anther organic light emitting display panel according to an embodiment of the present disclosure. As shown in FIG. 4, the organic light emitting display panel further includes a thin film encapsulation layer 6. The thin film encapsulation layer 6 is placed on a surface of the cathode layer 1 away from the anode layer 2.

In the prior art, a cathode layer made of translucent metal material generates a strong microcavity effect, a part of optical energy is absorbed and consumed by total reflection, which result in a low utilization of output light, so that a light extraction layer is required to be placed between the cathode layer and the thin film encapsulation layer, for improving the luminous efficiency. In the organic light emitting display panel of the embodiments of the present disclosure, the cathode layer 1 is a transparent conductive layer, so that the light output efficiency is high, a light extraction layer is not necessary, and the thin film sealing layer 6 directly contacts with the cathode layer 1. Thus, the preparing cost of the organic light emitting display panel decreases, and the panel is thinner.

In another aspect, if using glass material for encapsulation, a vacuum environment exists between an encapsulation substrate and the cathode layer. When light emits from the cathode layer, light emits from an optically denser medium (cathode layer) to an optically thinner medium (vacuum), so that light is totally reflected on an interface of the cathode layer and vacuum, and thus light is repeatedly reflected between such interface and the totally reflective anode, which may result in the microcavity effect in a certain degree, and luminescent spectrum and luminous efficiency will be influenced. For further reducing such risk, furthermore, in the embodiment, a thin film encapsulation is adopted, the encapsulation layer directly covers a surface of the cathode layer, no vacuum environment exists, and the totally reflection is avoided, so that the luminescent spectrum and the luminous efficiency are prevented from being affected.

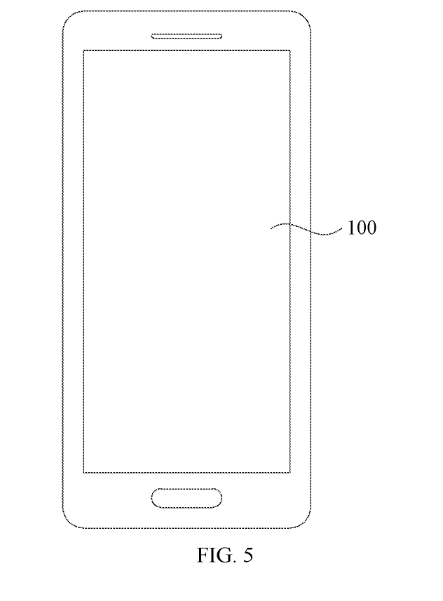

FIG. 5 illustrates a structural schematic diagram of a display device according to an embodiment of the present disclosure. As shown in FIG. 5, the display device includes the organic light emitting display panel 100 described as above.

A detailed configuration and a principle of the display panel 100 are the same as the embodiments described as above, which are not repeated herein. The display device can be any electronic device having a display function, such as touch display screen, mobile phone, tablet computer, notebook computer, E-book, and television.

In the display device of embodiments of the present disclosure, by doping the metal whose activity is stronger than activity of magnesium into the first electron transmission layer, the first electron transmission layer is capable of directly injecting electrons into the light emitting layer to make the light emitting layer emit light, so that it is unnecessary for the cathode layer to inject electrons into the light emitting layer, and a transparent conductive layer can be used as the cathode layer. Since the transmissivity of the transparent conductive layer is relatively high, the microcavity effect generated is weak, thereby improving the utilization of output light in the top emission configuration. In addition, in the prior art, the cathode layer is usually made of thin metal material to achieve an translucent effect, while the thinner the metal material, the greater its area resistance of the cathode layer. Thus, a pressure drop of the voltage transmitted on the cathode layer decreases, and the more easily a problem of non-uniformity of display brightness occurs. In the organic light emitting display panel of the present embodiment, the square resistance of the cathode layer is smaller than or equal to 10 Ω/□, so that a conductivity of the cathode layer is improved, thereby improving uniformity of display brightness.

Embodiments described above are merely preferred embodiments of the present disclosure and they do not limit the present disclosure. Any modification, equivalent replacement, and improvement made within the spirit and principle of the present disclosure shall fall into the scope of the present disclosure.

What is claimed is:

1. An organic light emitting display panel, comprising:
a cathode layer;
an anode layer;
an organic material layer placed between the cathode layer and the anode layer, the organic material layer comprising a first electron transmission layer, the first electron transmission layer being doped with a metal whose activity is stronger than magnesium; and
a substrate;
wherein a minimum transmittance of the cathode layer in visible light band is greater than 80%; a reflectivity of the anode layer in visible light band is greater than 90%; and
wherein the substrate, the anode layer, the organic material layer, and the cathode layer are placed in order along a light outputting direction of the organic light emitting display panel.

2. The organic light emitting display panel according to claim 1, wherein a square resistance of the cathode layer is smaller than or equal to 10 Ω/□.

3. The organic light emitting display panel according to claim 1, wherein a thickness of the cathode layer is greater than or equal to 2400 angstroms.

4. The organic light emitting display panel according to claim 1, wherein the cathode layer is made of indium tin oxide, indium zinc oxide, or a mixture of indium tin oxide and indium zinc oxide.

5. The organic light emitting display panel according to claim 4, wherein the cathode layer is doped with a metal material.

6. The organic light emitting display panel according to claim 5, wherein an atom percentage of the metal material in the cathode layer is smaller than 2%.

7. The organic light emitting display panel according to claim 6, wherein the metal material is gold, silver, copper, or aluminum.

8. The organic light emitting display panel according to claim 1, wherein a thickness of the first electron transmission layer is greater than 1000 angstroms.

9. The organic light emitting display panel according to claim 1, wherein a volume percentage of the metal whose activity is stronger than magnesium in the first electron transmission layer is in a range of 1%-5%.

10. The organic light emitting display panel according to claim 1, wherein the metal whose activity is stronger than magnesium is selected from a group consisting of lithium, sodium, calcium, cesium, and ytterbium.

11. The organic light emitting display panel according to claim 10, wherein the metal whose activity is stronger than magnesium is ytterbium.

12. The organic light emitting display panel according to claim 11, wherein the first electron transmission layer comprises a functional group shown as formula I; and any hydrogen atom in the functional group shown as formula I is available to be substituted to form a substituent group.

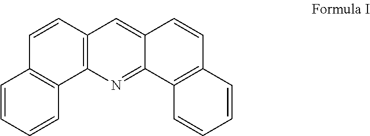 [SMILES: c1ccc2c(c1)ccc1cc3ccc4ccccc4c3nc12]

13. The organic light emitting display panel according to claim 11, wherein the first electron transmission layer comprises a compound shown as formula II.

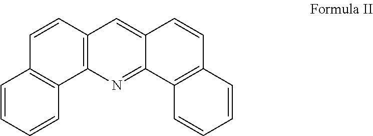 [SMILES: c1ccc2c(c1)ccc1cc3ccc4ccccc4c3nc12]

14. The organic light emitting display panel according to claim 1, wherein the organic material layer comprises the first electron transmission layer, a light emitting layer, a hole transmission layer, and a hole injection layer placed in order along a direction from the cathode layer to the anode layer.

15. The organic light emitting display panel according to claim 1, further comprising:
a color filter layer placed on one side of the cathode layer away from the anode layer,
wherein the organic material layer is an organic material layer used for emitting white light.

16. The organic light emitting display panel according to claim 15, wherein the organic material layer comprises the first electron transmission layer, a first light emitting layer, a first hole transmission layer, a first charge generation layer, a second charge generation layer, a second electron transmission layer, a second light emitting layer, a second hole transmission layer, a third charge generation layer, a fourth charge generation layer, a third electron transmission layer, a third light emitting layer, a third hole transmission layer, and a fifth charge generation layer placed in order along a direction from the cathode layer to the anode layer.

17. The organic light emitting display panel according to claim 16, wherein each of the second charge generation layer and the fourth charge generation layer comprises an N-type dopant and an electron transmission material, the N-type dopant is ytterbium, and the electron transmission material comprises a functional group shown as formula I or a compound shown as formula II; and
any hydrogen atom in the functional group shown as formula I is available to be substituted to form a substituent group;

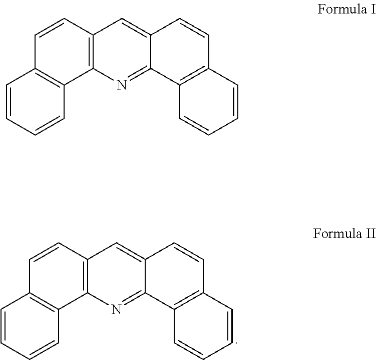 [SMILES: c1ccc2c(c1)ccc1cc3ccc4ccccc4c3nc12 ; c1ccc2c(c1)ccc1cc3ccc4ccccc4c3nc12]

18. The organic light emitting display panel according to claim 17, wherein the first light emitting layer is one of a blue-light emitting layer, a green-light emitting layer, and a red-light emitting layer, the second light emitting layer is another one of the blue-light emitting layer, the green-light emitting layer, and the red-light emitting layer, and the third light emitting layer is the remaining one of the blue-light emitting layer, the green-light emitting layer, and the red-light emitting layer.

19. The organic light emitting display panel according to claim 1, further comprising a thin film encapsulation layer, the thin film encapsulation layer being placed at a surface of the cathode layer away from the anode layer.

20. A display device, comprising an organic light emitting display panel, wherein the organic light emitting display panel comprises:
a cathode layer;
an anode layer;
an organic material layer placed between the cathode layer and the anode layer, the organic material layer comprising a first electron transmission layer, the first electron transmission layer being doped with a metal whose activity is stronger than magnesium; and
a substrate;
wherein a minimum transmittance of the cathode layer in visible light band is greater than 80%; a reflectivity of the anode layer in visible light band is greater than 90%; and
the substrate, the anode layer, the organic material layer, and the cathode layer are placed in order along a light outputting direction of the organic light emitting display panel.
